(19) United States
(12) Patent Application Publication
(10) Pub. No.: US 2012/0201399 A1
(43) Pub. Date: Aug. 9, 2012

(54) SOUND SIGNAL PROCESSING APPARATUS, SOUND SIGNAL PROCESSING METHOD, AND PROGRAM

(76) Inventor: Yuhki MITSUFUJI, Tokyo (JP)

(21) Appl. No.: 13/359,004

(22) Filed: Jan. 26, 2012

(30) Foreign Application Priority Data
Feb. 9, 2011 (JP) 2011-026241

(51) Int. Cl. H03G 5/00

(52) U.S. Cl. 381/98

(57) ABSTRACT

A sound signal processing apparatus includes a frequency analysis unit which executes frequency analysis of an input sound signal; a low-frequency envelope calculating unit which calculates low-frequency envelope information as envelope information of a low-frequency band based on a result of the frequency analysis; a high-frequency envelope information estimating unit which applies learned data generated in advance based on a sound signal for learning and generates estimated high-frequency envelope information corresponding to an input signal from the low-frequency envelope information corresponding to the input sound signal; and a frequency synthesizing unit which synthesizes a high-frequency band signal corresponding to the estimated high-frequency envelope information generated by the high-frequency envelope information estimating unit with the input sound signal and generates an output sound signal in which a frequency band is expanded.

### BACKGROUND

The present disclosure relates to a sound signal processing apparatus, a sound signal processing method, and a program. More specifically, the present disclosure relates to a sound signal processing apparatus, a sound signal processing method, and a program according to which frequency band expansion processing is performed on an input signal.

In data communication and data recording processing, compression processing is performed in many cases to reduce the amount of data. When a sound signal is compressed and delivered or recorded, however, a frequency band component included in original sound data is lost in some cases.

Accordingly, when the compressed data is decompressed and reproduced, sound data which is different from the original sound data is reproduced in some cases.

Some configurations have been proposed in which the frequency part lost in the compression processing is restored and decompressed in the decompression processing of such compression data.

For example, Japanese Unexamined Patent Application Publication No. 2007-17908 discloses frequency hand expansion processing by which processing of generating a high-frequency signal lost in the compression processing is performed.

However, there is a problem in that it is difficult to perform highly accurate expansion processing with a simple configuration while processing burden, processing time, and costs as an apparatus are increased in order to realize highly accurate expansion, as a problem in the band expansion processing in the related art.

### SUMMARY

It is desirable to provide a sound signal processing apparatus, a sound signal processing method, and a program which realize more accurate band expansion processing with a simple configuration.

According to a first embodiment of the present disclosure, there is provided a sound signal processing apparatus including: a frequency analysis unit which executes frequency analysis of an input sound signal; a low-frequency envelope calculating unit which calculates low-frequency envelope information as envelope information of a low-frequency band based on a result of the frequency analysis by the frequency analysis unit; a high-frequency envelope information estimating unit which applies learned data generated in advance based on a sound signal for learning, which is learned data for calculating high-frequency envelope information as envelope information of a high-frequency band from the low-frequency envelope information, and generates estimated high-frequency envelope information corresponding to an input signal from the low-frequency envelope information corresponding to the input sound signal; and a frequency synthesizing unit which synthesizes a high-frequency band signal corresponding to the estimated high-frequency envelope information generated by the high-frequency envelope information estimating unit with the input sound signal and generates an output sound signal in which a frequency band is expanded.

In addition, the learned data may include envelope gain information with which high-frequency envelope gain information is estimated from low-frequency envelope gain information, and envelope shape information with which high-frequency envelope shape information is estimated from low-frequency envelope shape information, and the high-frequency envelope information estimating unit may include a high-frequency envelope gain estimating unit which applies the envelope gain information included in the learned data and estimates the estimated high-frequency envelope gain information corresponding to the input signal from the low-frequency envelope gain information corresponding to the input sound signal, and a high-frequency envelope shape estimating unit which applies the envelope shape information included in the learned data and estimates the estimated high-frequency envelope shape information corresponding to the input signal from the low-frequency envelope shape information corresponding to the input sound signal.

Moreover, the high-frequency envelope shape estimating unit may input shaped low-frequency envelope information generated by filtering processing on the low-frequency envelope information of the input sound signal, which has been calculated by the low-frequency envelope calculating unit, and estimate the estimated high-frequency envelope shape information corresponding to the input signal.

Furthermore, the frequency analysis unit may perform time frequency analysis on the input sound signal and generate a time frequency spectrum.

In addition, the low-frequency envelope calculating unit may input a time frequency spectrum of the input sound signal, which has been generated by the frequency analysis unit, and generate a low-frequency cepstrum.

Moreover, the high-frequency envelope information estimating unit may include a high-frequency envelope gain estimating unit which applies the envelope gain information included in the learned data and estimates the estimated high-frequency envelope gain information corresponding to the input signal from the low-frequency envelope gain information corresponding to the input sound signal, and thee high-frequency envelope gain estimating unit may apply the envelope gain information included in the learned data to low-frequency cepstrum information generated based on the input sound signal and estimate the estimated high-frequency envelope gain information corresponding to the input signal from the low-frequency envelope gain information corresponding to the input sound signal.

Furthermore, the high-frequency envelope information estimating unit may include a high-frequency envelope shape estimating unit which applies the envelope shape information included in the learned data and estimates the estimated high-frequency envelope shape information corresponding to the input signal from the low-frequency envelope shape information corresponding to the input sound signal, and the high-frequency envelope shape estimating unit may estimate the high-frequency envelope shape information corresponding to the input sound signal by processing with the use of the envelope shape information included in the learned data, based on shaped low-frequency cepstrum information generated based on the input sound signal.

In addition, the high-frequency envelope shape estimating unit estimates the high-frequency envelope shape information corresponding to the input sound signal by estimation processing with the use of GMM (Gaussian mixture model).

Moreover, the sound signal processing apparatus may further include a learning processing unit which generates the learned data based on the sound signal for learning including a frequency in a high-frequency band, which is not included in the input sound signal, and the high-frequency envelope information estimating unit may apply the learned data generated by the learning processing unit and generate the estimated high-frequency envelope information corresponding to the input signal from the low-frequency envelope information corresponding to the input sound signal.

According to a second embodiment of the present disclosure, there is provided a sound signal processing apparatus including: a function of calculating first envelope information from a first signal; a function of removing a DC component of the first envelope information in a time direction by filtering for the purpose of removing an environmental factor which includes at least one of a function of collecting sound and a delivering function; and a function of regarding second envelope information, which has obtained by linearly converting the first envelope information after the filtering, as envelope information of a second signal and synthesizing the second signal with the first signal.

According to a third embodiment of the present disclosure, there is provided a sound signal processing apparatus including: a function of calculating low-frequency envelope information from a low-frequency signal; a function of calculating a ratio at which the low-frequency envelope information belongs to a plurality of groups classified in advance by learning a large amount of data; a function of performing linear conversion on the low-frequency envelope information based on linear conversion equations respectively allotted to the plurality of groups and generating a plurality of high-frequency envelope information items; and a function of regarding high-frequency envelope information, which has been obtained by mixing the plurality of high-frequency envelope information items at a ratio at which the high-frequency envelope information items belong to the plurality of groups for the purpose of generating smooth high-frequency envelope information in a time axis, as envelope information of a high-frequency signal and synthesizing the high-frequency signal with the low-frequency signal.

According to a fourth embodiment of the present embodiment, there is provided a sound signal processing method according to which frequency band expansion processing is performed on an input sound signal in a sound signal processing apparatus, the method including: executing frequency analysis of an input sound signal by a frequency analysis unit; calculating low-frequency envelope information as envelope information of low-frequency band based on a result of executing the frequency analysis by a low-frequency envelope calculating unit; applying learned data generated in advance based on a sound signal for learning by a high-frequency envelope information estimating unit, which is learned data for calculating high-frequency envelope information as envelope information of a high-frequency band from the low-frequency envelope information, and generating estimated high-frequency envelope information corresponding to an input signal from the low-frequency envelope information corresponding to the input sound signal; and synthesizing by a frequency synthesizing unit a high-frequency band signal corresponding to the estimated high-frequency envelope information generated by the high-frequency envelope information estimating unit with the input sound signal and generating an output sound signal in which a frequency band is expanded.

According to a fifth embodiment of the present disclosure, there is provided a sound signal processing method according to which frequency band expansion processing is performed on an input sound signal in a sound signal processing apparatus, the method including: calculating first envelope information from a first signal; removing a DC component of the first envelope information in a time direction by filtering for the purpose of removing an environmental factor which includes at least one of a function of collecting sound and a delivering function; and regarding second envelope information, which has obtained by linearly converting the first envelope information after the filtering, as envelope information of a second signal and synthesizing the second signal with the first signal.

According to a sixth embodiment of the present disclosure, there is provided a sound signal processing method according to which frequency band expansion processing is performed on an input sound signal in a sound signal processing apparatus, the method including: calculating low-frequency envelope information from a low-frequency signal; calculating a ratio at which the low-frequency envelope information belongs to a plurality of groups classified in advance by learning a large amount of data; performing linear conversion on the low-frequency envelope information based on linear conversion equations respectively allotted to the plurality of groups and generating a plurality of high-frequency envelope information items; and regarding high-frequency envelope information, which has been obtained by mixing the plurality of high-frequency envelope information items at a ratio at which the high-frequency envelope information items belong to the plurality of groups for the further purpose of generating smooth high-frequency envelope information in a time axis, as envelope information of a high-frequency signal and synthesizing the high-frequency signal with the low-frequency signal.

According to a seventh embodiment of the present disclosure, there is provided a program which causes a sound signal processing apparatus to perform frequency band expansion processing on an input sound signal, the program including: causing a frequency analysis unit to execute frequency analysis of an input sound signal; causing a low-frequency envelope calculating unit to calculate low-frequency envelope information as envelope information of low-frequency band based on a result of executing the frequency analysis; causing a high-frequency envelope information estimating unit to apply learned data generated in advance based on a sound signal for learning by, which is learned data for calculating high-frequency envelope information as envelope information of a high-frequency band from the low-frequency envelope information, and generate estimated high-frequency envelope information corresponding to an input signal from the low-frequency envelope information corresponding to the input sound signal; and causing a frequency synthesizing unit to synthesize a high-frequency band signal corresponding to the estimated high-frequency envelope information generated by the high-frequency envelope information estimating unit with the input sound signal and generate an output sound signal in which a frequency band is expanded.

In addition, the program according to the present disclosure is a program which can be provided to an image processing apparatus or a computer system, for example, capable of executing various program codes by a recording medium or a communication medium in a computer-readable form. By providing such a program in a computer-readable form, it is possible to realize the progressing in accordance with the program on an information processing apparatus or a computer system.

Other purposes, features, advantages of the present disclosure will be clarified by embodiments of the present disclosure which will be described later and more detailed description based on the accompanying drawings. In addition, a system in this specification means a logical composite configuration of a plurality of apparatuses and is not limited to a configuration in which apparatuses with each configuration are mounted in the same case body.

According to configurations of the embodiments of the present disclosure, an apparatus and a method with which frequency band expansion processing is highly accurately performed on a sound signal are realized.

According to configurations of the embodiments of the present disclosure, low-frequency envelope information as envelope information of a low-frequency band is calculated based on a frequency analysis result of an input sound signal. Moreover, high-frequency envelope information corresponding to the input signal is estimated and generated from the low-frequency envelope information corresponding to the input sound signal by applying learned data based on the sound signal for learning, for example, learned data with which high-frequency envelope information as envelope information of a high-frequency band is calculated from the low-frequency envelope information. Furthermore, a high-frequency band signal corresponding to the high-frequency envelope information corresponding to the input signal, which has been generated in the estimation processing, is synthesized with the input sound signal to generate an output sound signal in which the frequency band is expanded. By estimating an envelope gain and an envelope shape of a high-frequency band with the use of the leaned data, highly accurate band expansion is realized.

### BRIEF DESCRIPTION OF THE DRAWINGS

FIG. 1 is a diagram illustrating a configuration example of a sound signal processing apparatus;

FIG. 2 is a diagram illustrating frequency analysis processing and envelope information calculation processing;

FIGS. 3A and 3B are diagrams showing a state in which a temporal variation in an envelope shape (more precisely, cepstrum for each degree) is different depending on a sound source;

FIGS. 4A and 4B are diagrams showing temporal variations in envelope shapes when DC components are included in the envelope shape of a sound signal and when DC components are not included therein;

FIG. 5 is a diagram showing time-series data of DC components in an envelope shape;

FIGS. 6A and 6B are diagrams showing states of frequency domains of envelope shape DC;

FIGS. 7A to 7D are diagrams illustrating processing of estimating an envelope shape by an envelope shape learning unit with reference to modeling data based on Kmeans and GMM;

FIGS. 8A and 8B are diagrams illustrating processing of estimating high-frequency envelope shape information, which is executed by a high-frequency envelope shape estimating unit with reference to modeling data based on Kmeans and GMM; and

FIGS. 9A and 9B are diagrams illustrating how mapping data is changed when mapping source is changed while exceeding a cluster boundary in the case of using each of (a) Kmeans and (b) GMM.

### DETAILED DESCRIPTION OF EMBODIMENTS

Hereinafter, description will be given of details of a sound signal processing apparatus, a sound signal processing method, and a program according to the present disclosure with reference to the drawings. The description will be given in the following order.

### 1. Concerning Overall Configuration of Sound Signal Processing Apparatus According to the Present Disclosure

### 2. Concerning Processing, of Each Component in Signal Processing Apparatus

### 2.1 Concerning Frequency Analysis Unit

### 2.2 Concerning Low-frequency Envelope Calculating Unit

### 2.3 Concerning High-frequency Envelope Calculating Unit

### 2.4 Concerning Envelope Information Shaping Unit

### 2.5 Concerning Envelope Gain Learning Unit and Envelope Shape Learning Unit

### 2.6 Concerning High-frequency Envelope Shape Estimating Unit

### 2.7 Concerning High-frequency Envelope Gain Estimating Unit

### 2.8 Concerning Mid-frequency Envelope Correcting Unit

### 2.9 Concerning High-frequency Envelope Correcting Unit

### 2.10 Concerning Frequency Synthesizing Unit

### [1. Concerning Overall Configuration of Sound Signal Processing Apparatus According to the Present Disclosure]

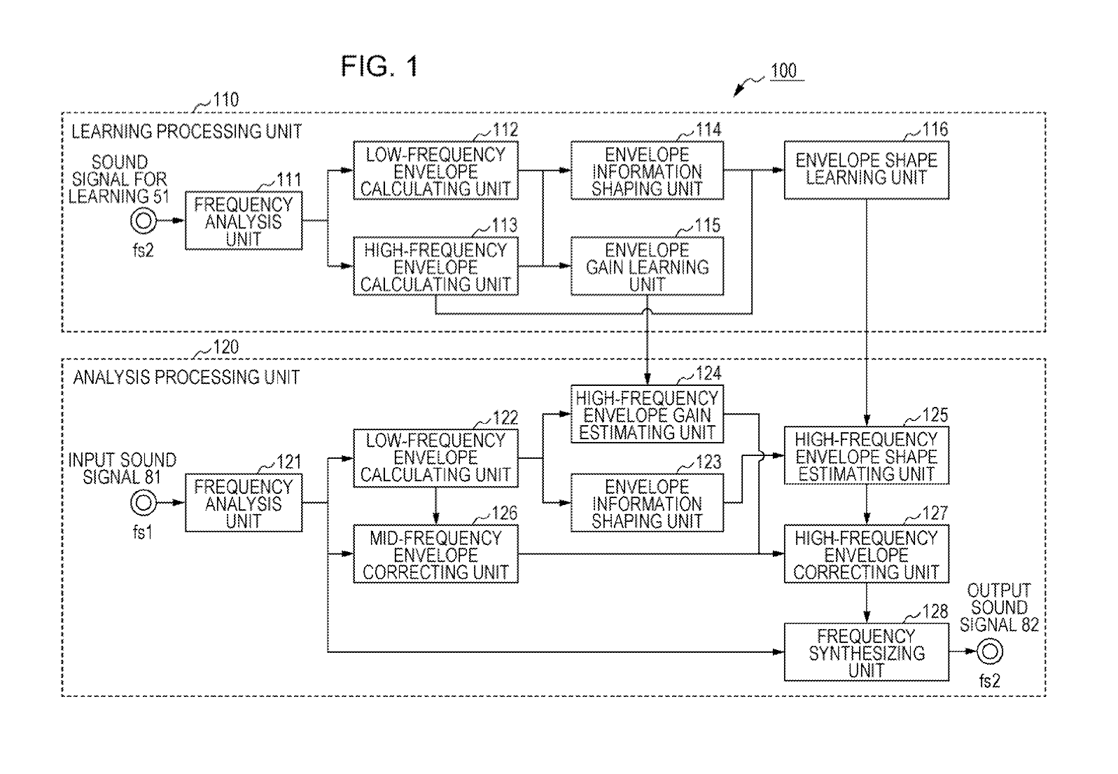

First, description will be given of an overall configuration of a signal processing apparatus according to embodiments of the present disclosure with reference to FIG. 1.

FIG. 1 is a diagram showing an example of a sound signal processing apparatus 100 according to embodiments of the present disclosure. The sound signal processing apparatus 100 shown in FIG. 1 includes a learning processing unit 110 in an upper stage and an analysis processing unit 120 in a lower stage.

An input sound signal 81 to be input to the analysis processing unit 120 is subjected to frequency band expansion processing and is output as an output sound signal 82. In the frequency band expansion processing executed by the analysis processing unit 120, the learning processing unit 110 uses data generated based on a sound signal 51 for learning.

The learning processing unit 110 inputs the sound signal 51 for learning, analyzes the sound signal 51 for learning, and generates learned data such as a frequency envelope or the like, for example. The analysis processing unit 120 uses a learning result generated by the learning processing unit 110 to perform frequency band expansion processing on the input sound signal 81.

As shown in FIG. 1, the learning processing unit 110 includes a frequency analysis unit 111, a low-frequency envelope calculating unit 112, a high-frequency envelope calculating unit 113, an envelope information shaping unit 114, an envelope gain learning unit 115, and an envelope shape learning unit 116.

In addition, the analysis processing unit 120 includes a frequency analysis unit 121, a low-frequency envelope calculating unit 122, an envelope information shaping unit 123, a high-frequency envelope gain estimating unit 124, a high-frequency envelope shape estimating unit 125, a mid-frequency envelope correcting unit 126, a high-frequency envelope correcting unit 127, and a frequency synthesizing unit 128.

The sampling frequency (fs2) of the sound signal 51 for learning to be input as a learning target by the learning processing unit 110 shown in FIG. 1 and the sampling frequency (fs2) of an output signal of the analysis processing unit 120, namely an output sound signal 82 after the frequency band expansion processing are the same.

The sampling frequency (fs2) of these two signals is a value which is double that of a sampling frequency (fs1) of the input signal of the analysis processing unit 120, namely the input sound signal 81 as a target of the frequency band expansion processing.

In addition, fs1 and fs2 respectively represent sampling frequencies, and the correspondence relationship of

(fs2)=2×(fs1)

is satisfied.

That is, the sampling frequency (fs1) of the input sound signal 81 input by the analysis processing unit 120 is a signal in which a frequency band is compressed, and the analysis processing unit 120 executes the processing of expanding the frequency band of the input signal and generates and outputs the output sound signal 82 of the sampling frequency (fs2) which is double.

In the band expansion processing, the analysis processing unit 120 obtains learned data for the sampling frequency (fs2) which is the same as the sampling frequency (fs2) of the output sound signal 82 from the learning processing unit 110 and uses the learned data to highly accurately execute frequency band expansion processing.

Hereinafter, detail description will be given of processing by each component.

### [2. Concerning Processing of Each Component in Signal Processing Apparatus]

### (2.1 Concerning Frequency Analysis Unit)

As shown in FIG. 1, the frequency analysis unit is set in each of the learning processing unit 110 and the analysis processing unit 120.

The frequency analysis unit 111 of the learning processing unit 110 shown in FIG. 1 inputs the sound signal 51 for learning of the sampling frequency (fs2) and performs frequency analysis on the sound signal 51 for learning.

In addition, the frequency analysis unit 121 of the analysis processing unit 120 performs time frequency analysis on the input sound signal 81 as the target of the frequency band expansion processing.

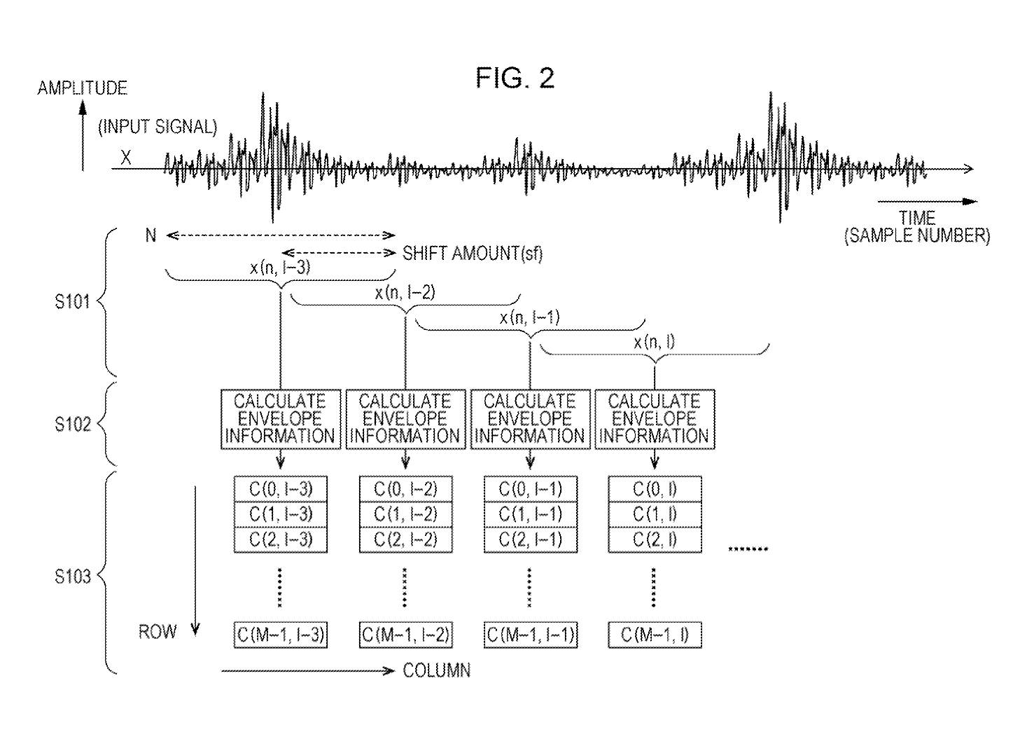

With reference to FIG. 2, description will be given of the time frequency analysis processing executed by the frequency analysis unit 111 and the frequency analysis unit 121.

The frequency analysis unit 111 and the frequency analysis unit 121 perform time frequency analysis on the input sound signal.

It is assumed that x represents an input signal to be input via a microphone or the like. An example of the input signal x is shown in the uppermost stage in FIG. 2. The horizontal axis represents time (or sample numbers) while the vertical axis represents amplitude.

The input signal x with respect to the frequency analysis unit 111 of the learning processing unit 110 is the sound signal 51 for learning of the sampling frequency (fs2).

In addition, the input signal x with respect to the frequency analysis unit 121 of the analysis processing unit 120 is the input sound signal 31 of the sampling frequency (fs1) which is the processing target signal in the frequency band expansion processing.

First, the frequency analysis unit 111 and the frequency analysis unit 121 performs frame division into a fixed size from the input signal x to obtain an input frame signal x(n, l).

This corresponds to the processing in Step S101 in FIG. 2.

In the example shown in FIG. 2, the setting is made such that the frame division size is N, the shift amount (sf) of each frame is 50% of the frame size N, and each of the frames is overlapped.

Moreover, the input frame signal x(n, l) is multiplied by a predetermined window function w to obtain a window function applied signal wx(n, l). The window function obtained by calculating a square root of a Hanning window is applicable, for example.

The window function applied signal wx(n, l) is expressed by the following (Equation 1).

$$wx ( n , l ) = {w}_{ana} ( n ) * x ( n , l ) ( \begin{matrix}x : INPUT SIGNAL \\ n : TIME INDEX \\ l : FRAME NUMBER \\ {w}_{ana} : WINDOW FUNCTION \\ wx : WINDOW FUNCTION APPLIED SIGNAL\end{matrix} ) \\ {w}_{ana} ( n ) = {( 0.5 - 0.5 * cos ( 2 π \frac{n}{N} ) )}^{0.5} ( N : FRAME SIZE ) \qquad EQUATION 1$$

In (Equation 1), each symbol is used as follows:

x: input signal;
n: time index where n=0, . . . , N−1, l=0, . . . , L−1 (N is a frame size);
l: frame number where l=0, . . . , L−1 (L is a total number of frames);
w_ana: window function; and
wx: window function applied signal.

Although the window function obtained by calculating a square root of a Hanning window is applied as the window function w_ana in the above example, a window function such as a sine window is also applicable in addition thereto.

The frame size N is a sampling number (N=sampling frequency fs*0.02) corresponding to 0.02 sec, for example. However, other sizes are also applicable.

Although the setting is made such that the frame shift amount (sf) is 50% of the frame size (N) and each frame is overlapped in the example shown in FIG. 2, other shift amounts are also applicable.

The time frequency analysis is performed on the window function applied signal wx(n, l) obtained by (Equation 1), based on the following (Equation 2) to obtain a time frequency spectrum Xana(k, l).

$${X}_{ana} ( k , l ) = {\sum }_{n = 0}^{M - 1} wx ( n , l ) * exp ( - j2π \frac{k * n}{M} ) ( \begin{matrix}wx : WINDOW FUNCTION APPLIED SIGNAL \\ j : PURE IMAGINARY NUMBER \\ M : POINT NUMBER OF D F T \\ k : FREQUENCY INDEX \\ {X}_{ana} : FREQUENCY SPECTRUM\end{matrix} ) \\ wx ( n , l ) = \{ \begin{matrix}wx ( n , l ) & n = 0 , … , N - 1 \\ 0 & n = N , … , M - 1\end{matrix} \qquad EQUATION 2$$

In (Equation 2), each symbol is used as follows:
wx: window function applied signal;
j: pure imaginary number;
M: point number of DFT (discrete Fourier transform);
k: frequency index; and
Xana: time frequency spectrum.

As the time frequency analysis processing with respect to the window function applied signal wx(n, l), frequency analysis based on DFT (discrete Fourier transform) is applicable, for example. In addition, another frequency analysis such as DCT (discrete cosine transform), MDCT (modified discrete cosine transform), or the like may be used. Moreover, zero-padding may appropriately be performed, if necessary, in accordance with the point number M of DFT (discrete Fourier transform). Although the point number M of DFT is set to a power of two which is equal to or greater than N, another point number is also applicable.

### (2.2 Concerning Low-Frequency Envelope Calculating Unit)

The low-frequency envelope calculating unit is also set in each of the learning processing unit 110 and the analysis processing unit 120 as shown in FIG. 1 in the same manner as the frequency analysis unit.

The low-frequency envelope calculating unit 112 of the learning processing unit 110 calculates low-frequency envelope information in the processing with respect to the spectrum corresponding to the frequency of the low-frequency band (less than fs1/2, for example) selected from the time frequency spectra obtained as the analysis result by the frequency analysis unit 111 with respect to the sound signal 51 for learning of the sampling frequency (fs2).

On the other hand, the low-frequency envelope calculating unit 122 of the analysis processing unit 120 calculates low-frequency envelope information in the processing with respect to the spectrum corresponding to the frequency of the low frequency band (less than fs1/2, for example) selected from the time frequency spectra obtained as the analysis result by the frequency analysis unit 121 with respect to the input sound signal 81 of the sampling frequency (fs1).

These two components including the low-frequency envelope calculating unit 112 and the low-frequency envelope calculating unit 122 execute the same processing while the processing targets thereof are different. That is, these two components calculate low-frequency envelope information in the processing with respect to the spectrum corresponding to the frequency of the low-frequency band (less than fs1/2, for example) selected from the time frequency spectra obtained as the analysis result by the frequency analysis unit.

Hereinafter, this processing will be described.

The low-frequency envelope calculating units 112 and 122 removes fine structures of the spectrum from the time frequency spectrum Xana(k, l) corresponding to the frequency of equal to or greater than 0 and less than fs1/2 supplied from the frequency analysis units 111 and 121 and calculate the envelope information. For example, the low-frequency cepstrum C_{low} corresponding to the low-frequency envelope information is calculated based on the following (Equation 3).

$${C}_{low} ( i , l ) = \frac{1}{M} {\sum }_{k = 0}^{M - 1} log ( \vert {X}_{ana} ( k , l ) \vert ) * exp ( j2π \frac{i * k}{M} ) . ( \begin{matrix}i : CEPSTRUM INDEX \\ {C}_{low} : LOW \text{-} FREQUENCY CEPSTRUM\end{matrix} ) \qquad EQUATION 3$$

In (Equation 3), each symbol is used as follows:

i: cepstrum index; and
C_{low}: low-frequency cepstrum.

The processing by the low-frequency envelope calculating units 112 and 122 corresponds to the processing in Steps S102 and S103 shown in FIG. 2.

Step S102 shown in FIG. 2 is the processing of calculating low frequency envelope information corresponding to each frame based on (Equation 3).

Step S103 shows each element in a matrix of N rows and L columns where rows represent frequencies (frequency bins) and columns represent time (frames) in relation to the low-frequency envelope information corresponding to each frame calculated based on Equation 3.

As shown in (Equation 3), the low-frequency envelope calculating units 112 and 122 calculate LFCC (linear frequency cepstrum coefficient, hereinafter simply referred to as cepstrum) and uses only a coefficient of a lower degree term to obtain the low-frequency envelope information.

The processing of calculating the low-frequency envelope information by the low-frequency envelope calculating units 112 and 122 are not limited to the processing of applying LFCC (linear frequency cepstrum coefficient, hereinafter referred to as cepstrum) as described above, another configuration is also applicable in which another cepstrum such as LPCC (linear predictive cepstrum coefficient), MFCC (mel-frequency cepstrum coefficient), PLPCC (perceptual linear predictive cepstrum coefficient), or the like or other frequency envelope information is used, for example.

The low-frequency envelope calculating unit 112 of the learning processing unit 110 in the upper stage shown in FIG. 1 supplies the low-frequency cepstrum C_{low}(i, l) calculated for the sound signal 51 for learning based on (Equation 3) to the envelope gain learning unit 115 and the envelope information shaping unit 114.

In addition, the low-frequency envelope calculating unit 122 of the analysis processing unit 120 in the lower stage in FIG. 1 supplies the low-frequency cepstrum C_{low}(i, l) calculated for the input sound signal 81 based on (Equation 3) to the high-frequency envelope gain estimating unit 124 and the envelope information shaping unit 123.

### (2.3 Concerning High-Frequency Envelope Calculating Unit)

Next, description will be given of processing by the high-frequency envelope calculating unit.

The high-frequency envelope calculating unit is provided in the learning processing unit 110 as shown in FIG. 1.

The high-frequency envelope calculating unit 113 of the learning processing unit 110 calculates high-frequency envelope information in the processing with respect to the spectrum corresponding to the frequency of the high-frequency band (equal to or greater than fs1/2 and less than fs2/2, for example) selected from the time frequency spectra obtained as the analysis result by the frequency analysis unit 111 for the sound signal 51 for learning of the sampling frequency (fs2).

The high-frequency envelope calculating unit 113 removes a fine structure of the spectrum from the time frequency spectrum Xana(k, l) corresponding to the frequency of equal to or greater than fs1/2 and less than 2/2 supplied from the frequency analysis unit 111 and calculates the envelope information. A high-frequency cepstrum C_{high} corresponding to the high-frequency envelope information is calculated based on the following (Equation 4), for example.

$${C}_{high} ( i , l ) = \frac{1}{M} {\sum }_{k = 0}^{M - 1} log ( \vert {X}_{ana} ( k , l ) \vert ) * exp ( j2π \frac{i * k}{M} ) ( \begin{matrix}i : CEPSTRUM INDEX \\ {C}_{high} : HIGH \text{-} FREQUENCY CEPSTRUM\end{matrix} ) \qquad EQUATION 4$$

In (Equation 4), each symbol is used as follows:

i: cepstrum index
C_{high}: high-frequency cepstrum.

According to this embodiment, the envelope information is obtained by calculating LFCC (linear frequency cepstrum coefficient, hereinafter referred to as cepstrum) and using only the coefficient of a lower grade term as described above. However, in the calculation of the high-frequency envelope information by the high-frequency envelope calculating unit 113, another configuration is also applicable in which not only LFCC (linear frequency cepstrum coefficient; hereinafter referred to as a cepstrum) but another cepstrum such as LPCC (linear predictive cepstrum coefficient), MFCC (mel-frequency cepstrum coefficient), PCPCC (perceptual linear predictive cepstrum coefficient), or the like or another frequency envelope information is used.

The low-frequency envelope calculating unit 112 of the learning processing unit 110 in the upper stage shown in FIG. 1 supplies the high-frequency cepstrum C_{high}(i, l) calculated for the sound signal 51 for learning based on (Equation 4) to the envelope information shaping unit 114, the envelope gain learning unit 115, and the envelope shape learning unit 116.

### (2.4 Concerning Envelope Information Shaping Unit)

The envelope information shaping unit is set in each of the learning processing unit 110 and the analysis processing unit 120 as shown in FIG. 1.

The envelope information shaping unit 114 of the learning processing unit 110 inputs the low-frequency envelope information generated by the low-frequency envelope calculating unit 112 based on the sound signal 51 for learning of the sampling frequency (fs2), executes the shaping of the envelope information in filtering processing, generates shaped envelope information, and provides the shaped envelope information to the envelope shape learning unit 116.

On the other hand, the envelope information shaping unit 123 of the analysis processing unit 120 inputs the low-frequency envelope information, generated by the low-frequency envelope calculating unit 122 based on the input sound signal 81 of the sampling frequency (fs1), executes the shaping of the envelope information in the processing of filtering the envelope information, generates shaped envelope information, and provides the shaped envelope information to the high-frequency envelope shape estimating unit 125.

More specifically, the envelope information shaping unit 114 of the learning processing unit 110 inputs the low-frequency envelope information generated by the low-frequency envelope calculating unit 112, namely the low-frequency cepstrum C_{low}(i, l) calculated based on (Equation 3), based on the sound signal 51 for learning of the sampling frequency (fs2), executes shaping of the envelope information, in which filtering processing is performed to cause to remain the envelope information C_{low}(i, l) up to a predetermined degree R and delete the envelope information C_{low}(i, l) thereafter, generates the shaped envelope information C′_{low}(i, l), and provides the shaped envelope information C′_{low}(i, l) to the envelope information learning unit 116.

On the other hand, the envelope information shaping unit 123 of the analysis processing unit 120 inputs the low-frequency envelope information generated by the low-frequency envelope calculating unit 122, namely the low-frequency cepstrum C_{low}(i, l) calculated based on (Equation 3), based on the input sound signal 81 of the sampling frequency (fs1), performs filtering processing on the envelope information C_{low}(i, l) for each degree in the frame direction, executes shaping, in which DC components at a modulation frequency and high-frequency components of equal to or greater than 25 Hz are removed, generates shaped envelope information (C′_{low}(i, l)), and provides the shaped envelope information (C′_{low}(i, l)) to the high-frequency envelope shape estimating unit 125.

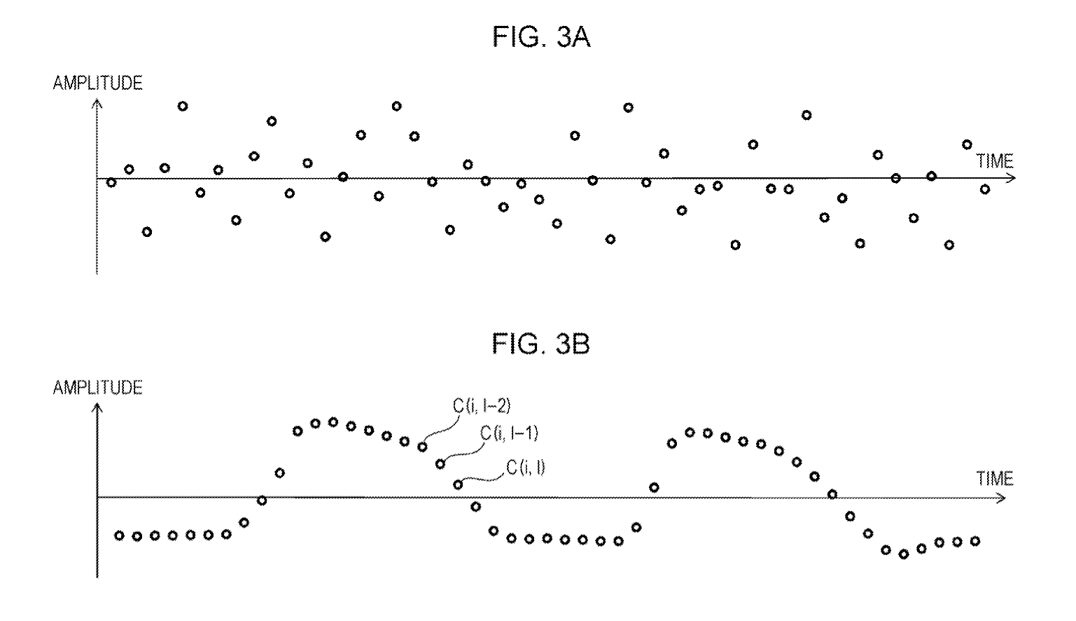

FIGS. 3A and 3B are diagrams showing a state in which a temporal variation in an envelope shape (more precisely, cepstrum for each degree) is different depending on a sound source.

(a) a temporal variation in an envelope shape of a non-sound signal
(b) a temporal variation in an envelope shape of a sound signal

FIGS. 3A and 3B show examples of the temporal variations in envelope shape of sound signals from the above two different sound sources.

The vertical axes represent amplitudes (frequencies) while the horizontal axes represent time.

It can be seen from (a) the temporal variation in the envelope shape of the non-sound signal that uniform periodic components from the low frequency to the high frequency are mixed with a random phase.

On the other hand, in (b) the temporal variation in the envelope shape of the sound signal, rising and falling of sound regularly vary while including a constant frequency (mainly equal to or less than 25 Hz).

It can be determined from the above facts that the sound signal is relatively dominant in the temporal variation of less than 25 Hz while the non-sound signal is relatively dominant in the temporal variation of equal to or greater than 25 Hz in the case of the signal with the sound signal and the non-sound signal mixed therein.

Accordingly, it is possible to estimate an effect of suppressing a temporal variation in a non-sound signal and an effect of suppressing and stabilizing a rapid temporal variation between frames by removing or reducing high-frequency temporal variation components of equal to or greater than 25 Hz.

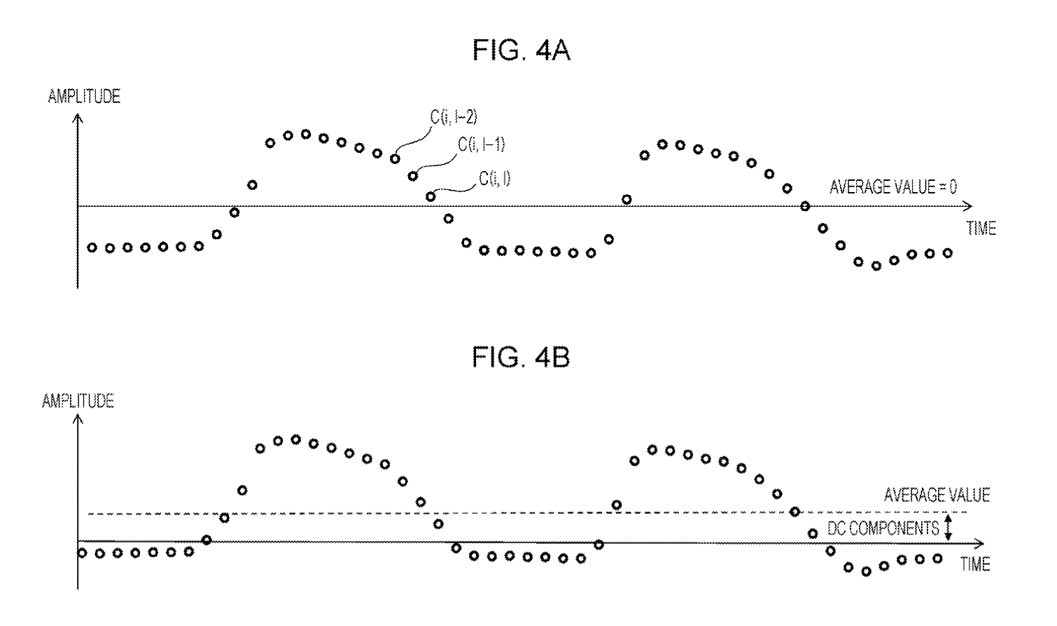

FIGS. 4A and 4B are diagrams showing temporal variations in envelope shapes when DC components are included in the envelope shape of a sound signal and when DC components are not included therein.

(c) a temporal variation in an envelope shape of a sound signal which does not include DC components
(d) a temporal variation in an envelope shape of a sound signal which includes DC components

FIGS. 4A and 4B show examples of temporal variations in the envelope shapes of such two sound signals.

The vertical axes represent amplitudes (frequencies) while the horizontal axes represent time.

The temporal variation data of the envelope shape of the sound signal which does not include DC components shown as (c) has a theoretical average value of 0 when an average of the entire section is calculated.

On the other hand, the temporal variation data of the envelope shape of the sound signal which includes DC components shown as (d) has a theoretical average value which is equal to the DC components, when an average of the entire section is calculated.

The thus calculated DC components in the time direction are different from each other for each cepstrum degree.

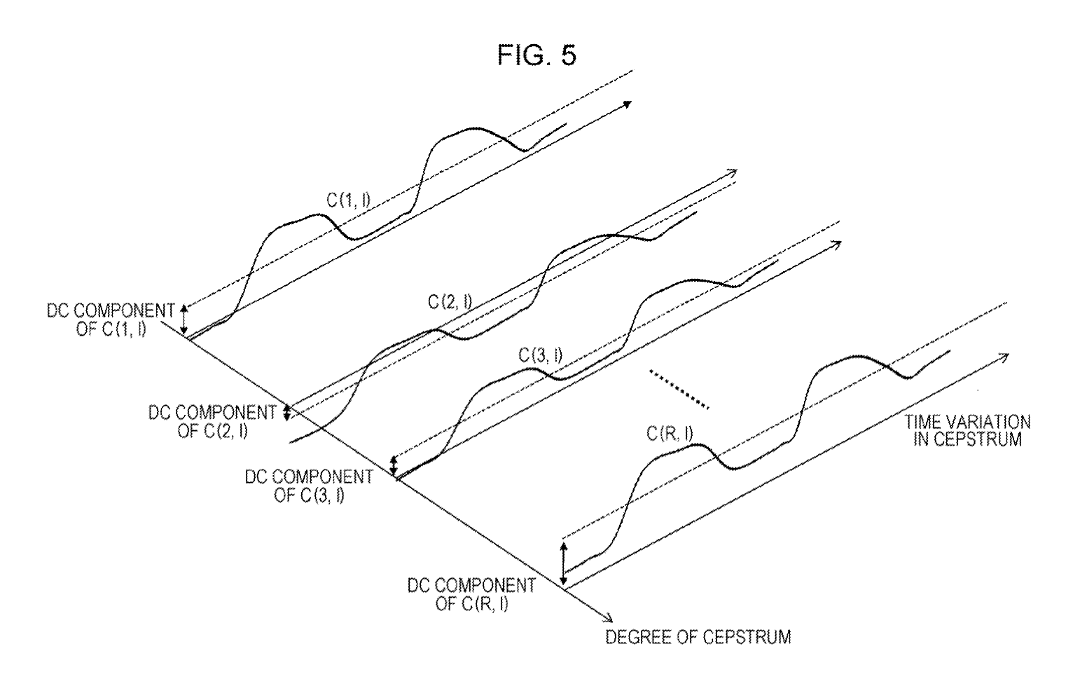

FIG. 5 shows a time-sires state of the envelope shape DC component. The cepstra of first to R-th degrees are arranged from the left furthest part to the closest part, and the temporal variations in the cepstra are arranged from the closest part to the right furthest part.

Each of the cepstrum components from the first to R-th degrees shows temporal variation and respectively has a unique DC component.

When the DC components from the first to R-th degrees are subjected to frequency conversion, returned to a power spectrum axis, and observed, it is possible to obtain a time-invariant frequency envelope shape.

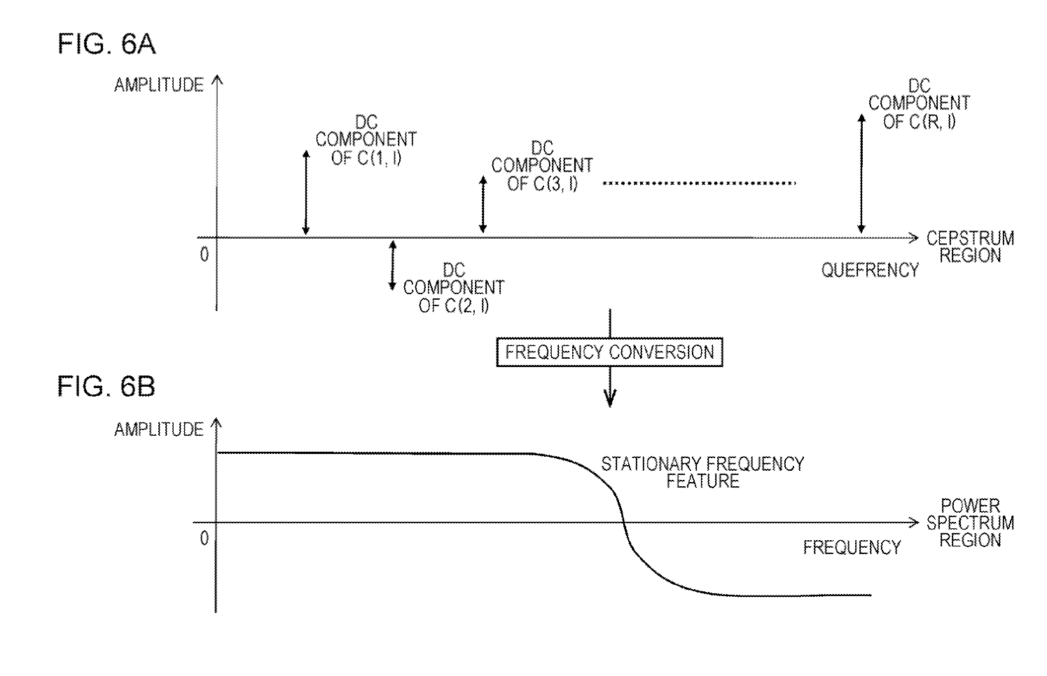

FIGS. 6A and 6B are diagrams showing states of frequency domains of envelope shape DC components.

FIG. 6A shows cepstra from the first to R-th degrees observed as DC components in a quefrency domain.

The data obtained by subjecting the cepstra from the first to R-th degree observed as DC components in the quefrency domain shown in FIG. 6A to the frequency conversion and returning the cepstra to a power spectrum domain corresponds to the data shown in FIG. 6B.

As shown in FIG. 6B, a stationary frequency feature is observed.

By subjecting the DC components from the first to R-th degrees to the frequency conversion and returning the DC components to the power spectrum axis, and observing the DC components, as described above, it is possible to obtain the stationary frequency envelope shape.

The frequency feature of the DC components shown in FIG. 6B is a constant frequency envelope without depending on the temporal variation and corresponds to an analog feature or an echo component of a microphone at the time of collecting sound or a codec pre-post filter feature in many cases.

By removing such DC components, there is an advantage in that multiplicative distortion (a microphone feature, an echo) is reduced.

In view of the aforementioned facts, it is preferable that the envelope information shaping unit 114 of the learning processing unit 110 and the envelope information shaping unit 123 of the analysis processing unit 120 perform processing on the filter passing band in the envelope information shaping processing in consideration of temporal variations which may occur in the sound temporal envelope in multiple sound sources.

The envelope information shaping unit 114 of the learning processing unit 110 and the envelope information shaping unit 123 of the analysis processing unit 120 generate shaped envelope information based on the following (Equation 5), for example.

$${C}_{low}^{′} ( i , l ) = {\sum }_{m = 0}^{{M}_{B} - 1} b ( m ) * {C}_{low} ( i , l - m ) + {\sum }_{m = 1}^{{M}_{A} - 1} a ( m ) * {C}_{low}^{′} ( i , l - m ) \qquad EQUATION 5$$

In (Equation 5), a modulation frequency is set to 100 Hz (=1/(0.02 *0.5)), a coefficient b(m) of a numerator of a filter transfer function is set to [0.25, 0.25, −0.25, −0.25], a coefficient a(m) of a denominator is set to [1, −0.98], and the total numbers of the coefficients are respectively set to MB=4 and MA=2.

In addition, the coefficients a(m) and b(m) can be set in accordance with the modulation frequency.

The envelope information shaping unit 114 of the learning processing unit 110 inputs the low-frequency envelope information generated by the low-frequency envelope calculating unit 112, namely the low-frequency cepstrum C_{low}(i, l) calculated based on (Equation 3), based on the sound signal 51 for learning of the sampling frequency (fs2), generates shaped envelope information C′_{low}(i, l) for the envelope information C_{low}(i, l) based on (Equation 5), and provides the shaped envelope information C′_{low}(i, l) to the envelope information learning unit 116.

On the other hand, the envelope information shaping unit 123 of the analysis processing unit 120 inputs the low-frequency envelope information generated by the low-frequency envelope calculating unit 122, namely the low-frequency cepstrum C_{low}(i, l) calculated based on (Equation 3), based on the input sound signal 81 of the sampling frequency (fs1), generates shaped low-frequency envelope information, namely shaped low-frequency cepstrum information (C′_{low}(i, l)) for the envelope information C_{low}(i, l) based on (Equation 5), and provides the information to the high-frequency envelope shape estimating unit 125.

### (2.5 Concerning Envelope Gain Learning Unit and Envelope Shape Learning Unit)

The envelope gain learning unit 115 and the envelope shape learning unit 116 are set in the learning processing unit 110 as shown in FIG. 1.

The envelope gain learning unit 115 and the envelope shape learning unit 116 learn the relationship between the low-frequency envelope information and the high-frequency envelope information in the sound signal 51 for learning based on the following envelope information generated based on the sound signal 51 for learning:

low-frequency cepstrum information C_{low}(i, l);
high-frequency cepstrum information C_{high}(i, l); and
shaped cepstrum information C′_{low}(i, l).

Specifically, the envelope gain learning unit 115 calculates [envelope gain estimation information A] as envelope gain information for estimating the high-frequency envelope gain information from the low-frequency envelope gain information.

In addition, the envelope shape learning unit 116 calculates [mixing number P], [mixing coefficient πp], [average μp], and [covariance Σp] as envelope shape information for estimating the high-frequency envelope shape information from the low-frequency envelope shape information.

The envelope gain learning unit 115 and the envelope shape learning unit 116 separately estimate the envelope gain and the envelope shape.

The envelope gain learning unit 115 executes the envelope gain as processing of estimating 0-th degree component of the cepstrum.

The envelope shape learning unit 116 realizes the envelope shape by estimating the lower components of the cepstrum other than the 0-th degree component.

Specifically, the envelope gain learning unit 115 performs processing of estimating the 0-th component of the cepstrum by a regression expression, for example, to calculate the envelope gain.

On the other hand, the envelope shape learning unit 116 estimates the lower degree components of the cepstrum other than the 0-th degree component by a GMM (Gaussian mixture model), for example, to calculate the envelope shape.

In the envelope gain estimation processing by the envelope gain learning unit 115, the 0-th to R-th degree components of the low-frequency cepstrum information C_{low}(i, l) and the square values thereof are used as explanatory variables, and the 0-th degree component C_{high}(0, 1) of the high-frequency cepstrum information is used as explained variable. A linear coupling coefficient A which minimizes a square sum error function E(A) between an estimated value (including an intercept term) by linear coupling of the above explanatory variables and the explained variable as a target value is obtained as [envelope gain estimation information A]. The square sum error function E(A) is expressed by the following (Equation 6).

$${{C}^{⋒}}_{high} ( 0 , l ) = A ( 0 ) + {\sum }_{i = 0}^{R} A ( i + 1 ) * {C}_{low} ( i , l ) + {\sum }_{i = 0}^{R} A ( i + R + 2 ) * {( {C}_{low} ( i , l ) )}^{2} \\ E ( A ) = \frac{1}{2} {\sum }_{l = 0}^{L - 1} {( {\hat{C}}_{high} ( 0 , l ) - {C}_{low} ( 0 , l ) )}^{2} \qquad EQUATION 6$$

In (Equation 6), non-linear regression including a square is performed while R is set to 4, for example.

In addition, another R value may be used, or another regression method such as a neural network, kernel regression, or the like may be used.

In the estimation of the envelope shape by the envelope shape learning unit 116, processing with the use of GMM (Gaussian mixture model), for example, is performed.

In the estimation of the envelope shape by the envelope shape learning unit 116, lower degree components of the cepstrum other than the 0-th degree component are estimated with the use of GMM (Gaussian mixture model), for example, to calculate the envelope shape. Specifically, [mixing number P], [mixing coefficient πp], [average μp], and [covariance Σp] as the envelope shape information are calculated.

As a method for the processing of estimating the lower degree components of the cepstrum other than the 0-th degree component, which is performed as the processing of estimating the envelope shape, it is possible to apply a Kmeans method which is frequently used as a method of vector quantization in codec, for example, as well as the processing with the use of GMM (Gaussian mixture model). However, GMM is a modeling method with a high degree of freedom as compared with Kmeans. Specifically, it is possible to apply processing with the use of a clustering method (vector quantization method) of an envelope shape, for example. In addition, GMM becomes substantially the same as Kmeans in theory when the degrees of freedom in covariance in all clusters are decreased to obtain a unit matrix.

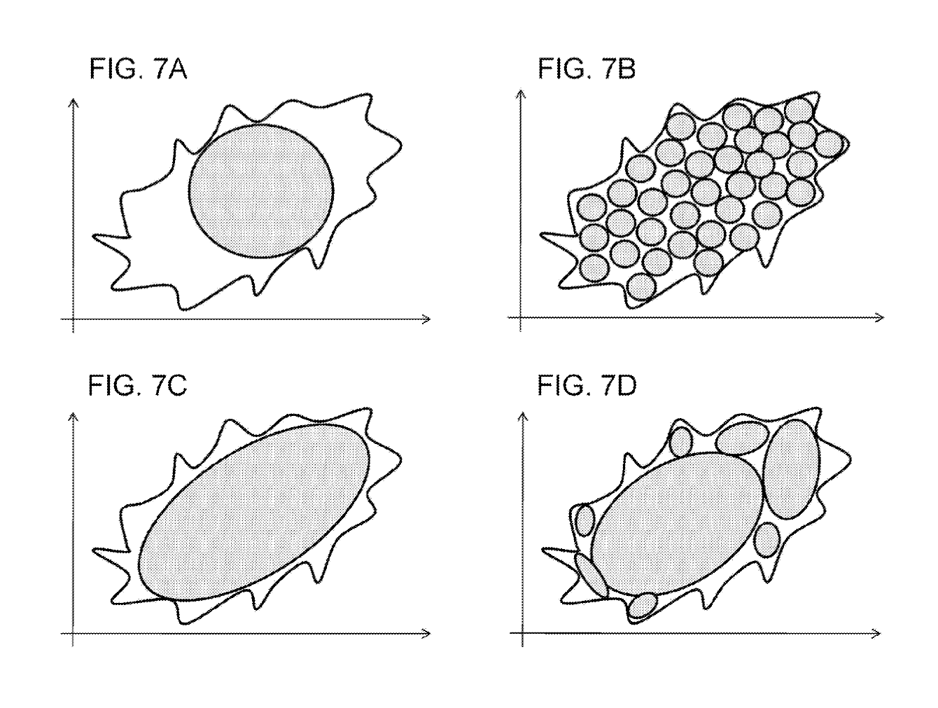

FIGS. 7A to 9B are diagrams showing comparison of modeling based on Kmeans and GMM.

In addition, the models shown in FIGS. 7A to 9B are shown while a multidimensional feature space is simplified into a two-dimensional feature space.

FIGS. 7A to 7D show the following modeling data examples:

(a) an example in which modeling is performed based on Kmeans (cluster number: P=1);
(b) an example in which modeling is performed based on Kmeans (cluster number: P>1);
(c) an example in which modeling is performed based on GMM (cluster number: P=1); and
(d) an example in which modeling is performed based on GMM (cluster number: P>1).

FIG. 7A shows an example in which modeling is performed based on Kmeans (cluster number: P=1).

When the figure with a distorted shape surrounding the outside of the circle in the'drawing shows data distribution in a space, modeling in hyperspherical distribution is performed if modeling is performed based on Kmeans (cluster number: P=1), and many parts which are not sufficiently be expressed appear. In FIGS. 7A to 7D, gray circles or ellipses are modeled spaces, and other parts are spaces which are not modeled.

As described above, a distorted space is not expressed with a single cluster in many cases according to the superspherical model such as Kmeans. Therefore, multiple clusters (cluster number: P>1) are typically used to fill in the space distribution as in (b) in many cases.

On the other hand, since it is possible to flexibly change the shape from a supersupherical shape to a superelliptical shape due to the degree of freedom in the covariant of the model in the case of (c) the example in which modeling is performed based on GMM (cluster number: P 1), the volume corresponding to the data distribution becomes larger than that in the case of Kmeans.

Since it is possible to independently change the size, the direction, and the shape of each cluster even in the case in which a plurality of clusters are used as in (d) the example in which modeling is performed based on GMM (cluster number: P>1), the volume corresponding to the distribution is large.

As can be understood from FIGS. 7A to 7D, the data distribution can be expressed more precisely in (c) the example in which modeling is performed based on GMM (cluster number: P=1) than in (a) the example in which modeling is performed based on Kmeans (cluster number: P=1), when the cluster number is one in the same manner.

In relation to the comparison between (b) and (c), both express the distribution more precisely than (a), the necessary cluster number is larger in (b), and it is necessary to provide a memory which holds the information. On the other hand, GMM shown in (c) holds covariant information of each cluster, and the information determines the sizes, the directions, and the shapes of the clusters. In the case of a model (diagonal covariant model) with a restriction in degree of freedom according to which all components other than diagonal components are zero, it is necessary to provide a memory which is twice as large as that in Kmeans under the condition of the same cluster numbers. This is because diagonal covariant information is held in GMM while only cluster average value information is held in Kmeans.

However, since the expression ability of GMM is significantly high in practice, and a cluster number of about four times as large as that in GMM is necessary in Kmeans for modeling a sound envelope shape as in embodiments, memory costs for Kmeans are higher in the result. Although additional costs are necessary for calculation burden of logs whose number is the same as the cluster number as compared with the case of Kmeans, the additional costs are extremely lower than the calculation burden in FFT or the like.

For such reasons, processing with the use of GMM (Gaussian mixture model), for example, is performed in the estimation of the envelope shape by the envelope shape learning unit 116.

In the estimation of the envelope shape by the envelope shape learning unit 116, lower degree components of the cepstrum other than the 0-th degree component are estimated with the use of GMM (Gaussian mixture model) to calculate the envelope shape. Specifically, [mixing number P], [mixing coefficient πp], [average μp], and [covariant Σp] as the envelope shape information are calculated.

In the actual learning processing, P parameters of Gaussian distributions, a mixing coefficient πp, an average μp, and covariant Σp are obtained by regarding shaped cepstrum information C′_{low}(i, l) and C_{high}(i, l) as one combined vector Call(i, l) and maximizing the log posterior probability based on an E, algorithm.

Specifically, [mixing number P], [mixing coefficient πp], [average μp], and [covariant Σp] as the envelope shape information are calculated based on the following (Equation 7).

$${C}_{all} ( r - 1 , l ) = \{ \begin{matrix}{C}_{low}^{′} ( r , l ) * {α}_{low} ( r - 1 ) & r = 1 , … , R \\ {C}_{high} ( r - R , l ) * {α}_{high} ( r - R - 1 ) & r = R + 1 , … , 2 * R\end{matrix} \\ {w}_{p} ( l ) = \frac{{π}_{p} * N ( {C}_{all} ( l ) \vert {μ}_{p} , {Σ}_{p} )}{{\sum }_{n = 0}^{P - 1} {π}_{n} * N ( {C}_{all} ( l ) \vert {μ}_{n} , {Σ}_{n} )} ( \begin{matrix}{w}_{p} : BURDEN RATIO OF EACH GAUSSIAN DISTRIBUTION \\ {L}_{p} : FRAME NUMBER BELONGING TO EACH GAUSSIAN DISTRIBUTION\end{matrix} ) \\ {μ}_{p}^{new} = \frac{1}{{L}_{p}} {\sum }_{l = 0}^{L - 1} {w}_{p} ( l ) * {C}_{all} ( l ) \\ {Σ}_{p}^{new} = \frac{1}{{L}_{p}} {\sum }_{l = 0}^{L - 1} {w}_{p} ( l ) * ( {C}_{all} ( l ) - {μ}_{p}^{new} ) * {( {C}_{all} ( l ) - {μ}_{p}^{new} )}^{T} \\ {π}_{p}^{new} = \frac{{L}_{p}}{L} \\ {L}_{p}^{new} = {\sum }_{l = 0}^{L - 1} {w}_{p} ( l ) \qquad EQUATION 7$$

When a combine vector is created, the shaped cepstrum information C′_{low}(i, l) and C_{high}(i, l) are respectively multiplied by predetermined weight coefficients αlow(r) and αhigh(r). For example, R is set to four, and [0.5, 0.75, 1.0, 1.25] is set for both the weight coefficients αlow(r) and αhigh(r). In addition, setting can be made for the weight coefficients in various manners.

As described above, the envelope gain learning unit 115 uses: explanatory variables, which are the 0-th to R-th degree components of the low-frequency cepstrum information C_{low}(i, l) and square values thereof; and explained variable, which is the o-th degree component C_{high}(0, i) of the high-frequency cepstrum information, calculates square sum error function E(A) between the estimation value (including an intercept term) by the linear coupling of the explanatory variables and the explained variable as the target value, based on (Equation 6), and obtains a linear coupling coefficient A which minimizes the square sum error function E(A) as [envelope gain estimation information A].

In addition, the envelope shape learning unit 116 uses GMM (Gaussian mixture model), for example, as described above and estimates the lower degree components of the cepstrum other than the 0-th degree component to calculate the envelope shape. Specifically, [mixing number p], [mixing coefficient πp], [average μp], and [covariant Σp] as the envelope shape information are calculated.

As shown in FIG. 1, the [envelope gain estimation information A] calculated by the envelope gain learning unit 115 is provided to the high-frequency envelope gain estimating unit 124 of the analysis processing unit 120.

In addition, [mixing number P], [mixing coefficient πp], [average μp], and [covariant Σp] calculated by the envelope shape learning unit 116 as the envelope shape information are provided to the high-frequency envelope shape estimating unit 125 of the analysis processing unit 120.

### (2.6 Concerning High-Frequency Envelope Shape Estimating Unit)

Next, description will be given of the processing by the high-frequency envelope shape estimating unit 125 provided in the analysis processing unit 120 shown in FIG. 1.

The high-frequency envelope shape estimating unit 125 in the analysis processing unit 120 inputs the shaped low-frequency cepstrum information C′_{low}(i, l) generated by the envelope information shaping unit 123 of the analysis processing unit 120 based on the input sound signal 81.

Moreover, the high-frequency envelope shape estimating unit 125 in the analysis processing unit 120 inputs [mixing number P], [mixing coefficient πp], [average μp], and [covariant Σp] as the envelope shape information obtained from the envelope shape learning unit 116 of the learning processing unit 110 as the analysis result based on the sound signal 51 for learning.

The high-frequency envelope shape estimating unit 125 estimates the high-frequency envelope shape information Ĉ_{high}(i, l) corresponding to the input sound signal 81 by executing the processing on the shaped low-frequency cepstrum information C′_{low}(i, l) generated based on the input sound signal 81 with the use of the envelope shape information based on the sound signal 51 for learning.

Here, i=1, . . . R is satisfied.

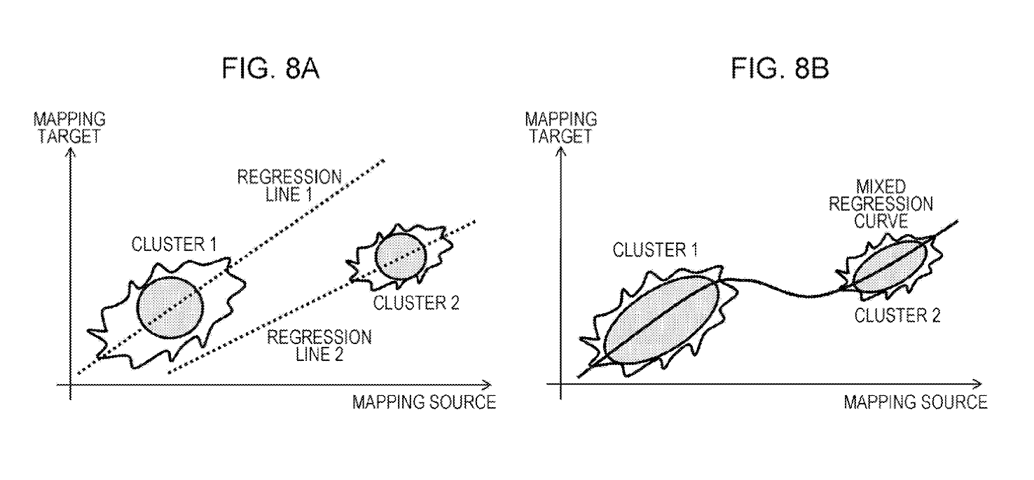

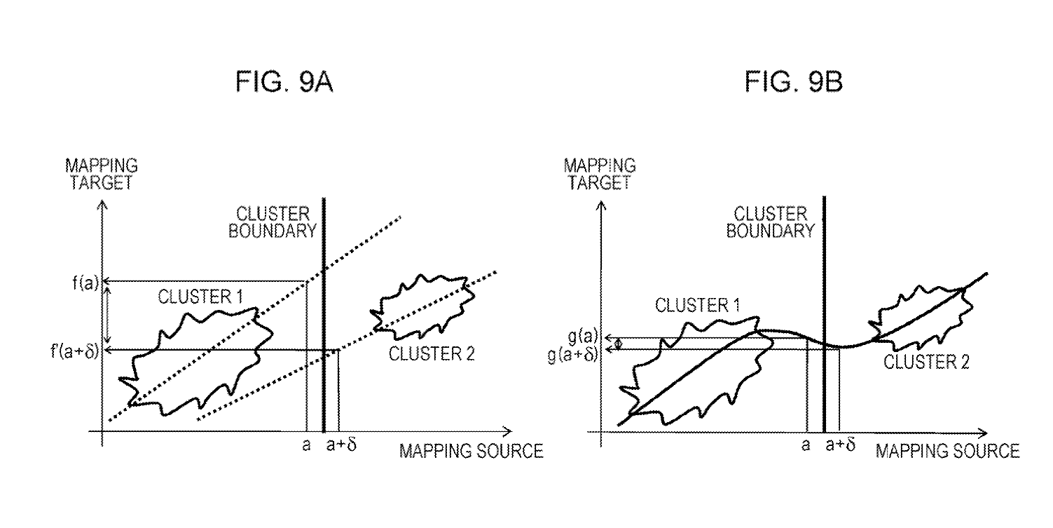

Referring to FIGS. 8A to 9D, description will be given of the processing of estimating the high-frequency envelope shape information, which is executed by the high-frequency envelope shape estimating unit 125. As described above, FIGS. 7A to 9D are diagrams showing comparison of modeling based on Kmeans and GMM, and the models in FIGS. 7A to 9D are shown while the multidimensional feature space is simplified into two-dimensional feature space.

FIGS. 8A to 9B are diagrams which depict how different the states of linear conversion from the low-frequency envelope shape (mapping source) to the high-frequency envelope shape (mapping target) are when two different methods of Kmeans and GMM are used.

In the case of Kmeans, after calculating to which cluster a mapping source belongs by measuring the distance to a centroid of the cluster, linear conversion from the low-frequency envelope shape to the high-frequency envelope shape is performed while the regression line of the cluster, to which the mapping source belongs, is regarded as a mapping function. The centroid of the cluster and the regression coefficient are determined in advance in the learning unit.

FIGS. 8A and 8B are diagrams illustrating the processing of:

(a) linear conversion processing using Kmeans+linear regression; and
(b) linear conversion processing using a posterior probability of GMM.

In the example of the linear conversion processing using Kmeans+linear regression shown in FIG. 8A, two clusters (cluster 1, cluster 2) are in the distribution of the two-dimensional feature space. Since the mapping source data and the mapping target data is present during the learning processing, both are used for the learning by clustering. Since the mapping target information is not known during the band expansion processing and only the low-frequency envelope information of the mapping source is held, the distance to the centroid of the cluster is calculated only with the use of the mapping source data, and the clustering is performed.

In the example shown in FIG. 8A, linear conversion is performed to obtain a mapping target result with the use of the regression line 1 when the distance to the centroid of the cluster is smaller for the cluster 1 or with the use of the regression line 2 when the distance to the centroid of the cluster is smaller for the cluster 2. Since the mapping function is switched from the regression line 1 to the regression line 2 when data is present at a cluster boundary, the obtained result is not stable, and discontinuation in the time direction frequently occurs.

In the example of the linear conversion processing when the posterior probability of GMM is used as shown in FIG. 8B, the distance is measured to obtain the cluster to which the mapping source belongs basically in the same manner as in Kmeans. However, GMM is different from Kmeans in that it is possible to calculate a probability as a ratio at which data is present at each cluster.

In the example shown in FIG. 8B, the closer the distance to the cluster 1 is, the higher the ratio at which the mapping source belongs to the cluster 1 becomes and the lower the ratio at which the mapping source belongs to the cluster 2 becomes. When the mapping source is closer to the cluster 2, an opposite result is obtained. By using presence probability of data in each cluster (typically referred to as a posterior probability of a cluster) with the use of the above feature and mixing the regression line of each cluster, it is possible to create a smooth mixing curve and thereby to realize a continuous mapping. In FIG. 8B, presence probabilities of two clusters are used, regression lines are mixed, and a mixing curve is depicted. The mapping source data is mapped by such a continuous mixing curve.

FIGS. 9A and 9B, similar to FIGS. 8A and 8B, are diagrams illustrating the processing examples of:

(a) linear conversion processing using Kmeans+linear regression; and
(b) linear conversion processing using posterior probability of GMM.

FIGS. 9A and 9B are diagrams illustrating how the mapping target data changes when the mapping source data exceeds the cluster boundary and changes in both cases of using (a) Kmeans and (b) GMM.

The drawings shows cases when the value of the mapping source data slightly changes from a to a+δ.

Since the cluster changes from 1 to 2 as shown in FIG. 9A when (a) the linear conversion processing using Kmeans+linear regression is performed, the regression coefficient used in the linear conversion is greatly changed, and a value of the mapping target is significantly changed.

On the other hand, since given mapping functions are mixed based on the presence probability to obtain a continuous mixing curve while the cluster changes from the cluster 1 to the cluster 2 as shown in FIG. 9B when (b) the linear conversion processing using the posterior probability of GMM is performed, a value of the mapping target is slightly changed.

This phenomenon is observed as a smoothness of the estimation result in the time direction.

According to the method of using GMM, it is possible to smoothly perform estimation between frames as described above, and a result which is relatively close to the temporal variation of an echo signal which is present in nature. When the distance between clusters is long, discontinuation in terms of a sound quality may occur in the method based on Kmeans, it is possible to achieve continuation in the method based on GMM. Since it is possible to expect an effect of complementing between clusters even if many clusters are not arranged, GMM can be realized with less clusters as compared with Kmeans, and it is possible to say that GMM is advantageous in terms of a cost performance.

The high-frequency envelope shape estimating unit 125 provided in the analysis processing unit 120 shown in FIG. 1 inputs the shaped low-frequency cepstrum information C′_{low}(i, l) generated by the envelope information shaping unit 123 in the analysis processing unit 120 based on the input sound signal 81, uses the envelope shape information obtained as an analysis result based on the sound signal 51 for learning input from the envelope shape learning unit 116 of the learning processing unit 110 to estimate the high-frequency envelope shape information Ĉ_{high}(i, l) corresponding to the input sound signal 81 based on the following (Equation 8) by applying the GMM method.

Specifically, the high-frequency envelope shape information Ĉ_{high}(i, l) corresponding to the input sound signal 81 is calculated by applying [mixing number P], [mixing coefficient πp], [average μp], and [covariant Σp] as the envelope shape information input from the envelope shape learning unit 116 of the learning processing unit 110 based on the following (Equation 8) which applies the GMM method.

$${{C}^{⋒}}_{high} ( l ) = {\sum }_{p = 0}^{P - 1} {w}_{p} * {\hat{y}}_{p} \\ {C}_{low}^{″} ( r - 1 , l ) = {C}_{low}^{′} ( r , l ) * {α}_{low} ( r - 1 ) \\ r = 1 , … , R \\ {w}_{p} = \frac{{π}_{p} * N ( {C}_{low}^{″} ( l ) \vert {μ}_{p}^{low} , {Σ}_{p}^{lowlow} )}{{\sum }_{n = 0}^{P - 1} {π}_{n} * N ( {C}_{low}^{″} ( l ) \vert {μ}_{n}^{low} , {Σ}_{n}^{lowlow} )} ( \begin{matrix}{w}_{p} : BURDEN RATIO OF EACH GAUSSIAN DISTRIBUTION \\ {\hat{y}}_{p} : \begin{matrix}MAPPING RESULT TO HIGH \text{-} FREQUENCY BAND IN \\ EACH GAUSSIAN DISTRIBUTION\end{matrix} \\ {\hat{C}}_{high} : ESTIMATED HIGH \text{-} FREQUENCY CEPSTRUM\end{matrix} ) \\ {\hat{y}}_{p} = {μ}_{p}^{high} + {{Σ}_{p}^{highlow} ( {Σ}_{p}^{lowlow} )}^{- 1} ( {C}_{low}^{″} ( l ) - {μ}_{p}^{low} ) \\ {μ}_{p} = ( \begin{matrix}{μ}_{p}^{low} \\ {μ}_{p}^{high}\end{matrix} ) \\ {Σ}_{p} = ( \begin{matrix}{Σ}_{p}^{lowlow} & {Σ}_{p}^{lowhigh} \\ {Σ}_{p}^{highlow} & {Σ}_{p}^{highhigh}\end{matrix} ) \qquad EQUATION 8$$

As described above, the high-frequency envelope shape estimating unit 125 multiplies the shaped low-frequency cepstrum information C′_{low}(i, l) generated based on the input sound signal 81 by the same weight coefficient αlow(r) as that at the time of learning and then estimates the high-frequency envelope shape information Ĉ_{high}(i, l) corresponding to the input sound signal 81 in the processing using the envelope shape information based on the sound signal 51 for learning.

Here, i=1, . . . , R is satisfied.

The high-frequency envelope shape estimating unit 125 supplies the estimated high-frequency cepstrum Ĉ_{high}(i, l) calculated based on (Equation 3) to the high-frequency envelope correcting unit 127.

### (2.7 Concerning High-Frequency Envelope Gain Estimating Unit)

Next, description will be given of the processing by the high-frequency envelope gain estimating unit 124 provided in the analysis processing unit 120 shown in FIG. 1.

The high-frequency envelope gain estimating unit 124 in the analysis processing unit 120 inputs the low-frequency cepstrum information C_{low}(i, l) generated by the low-frequency envelope calculating unit 122 in the analysis processing unit 120 based on the input sound signal 81.

Moreover, the high-frequency envelope gain estimating unit 124 in the analysis processing unit 120 inputs a [regression coefficient A] as the envelope gain information obtained by the envelope gain learning unit 115 of the learning processing unit 110 as an analysis result based on the sound signal 51 for learning.

The high-frequency envelope gain estimating unit 124 executes the processing using the [regression coefficient A] as the envelope gain information based on the sound signal 51 for learning on the low-frequency cepstrum information C_{low}(i, l) generated based on the input sound signal 81 to estimate the high-frequency envelope gain corresponding to the input sound signal 81.

Specifically, the high-frequency envelope gain is estimated by a regression model, and the 0-th degree component Ĉ_{high}(0, 1) is estimated based on the following (Equation 9). Here, i=0, . . . , R is satisfied.

$${{C}^{⋒}}_{high} ( 0 , l ) = A ( 0 ) + {\sum }_{i = 0}^{R} A ( i + 1 ) * {C}_{low} ( i , l ) + {\sum }_{i = 0}^{R} A ( i + R + 2 ) * {( {C}_{low} ( i , l ) )}^{2} \qquad EQUATION 9$$

In addition, the 0-th degree component Ĉ_{high}(0, l) of the high-frequency cepstrum represents the high-frequency envelope gain information. For example, R is set to four, and the non-linear regression including a square term is performed. However, another regression method such as a neural network, kernel regression, or the like may be used as the processing of estimating the high-frequency envelope gain as well as the processing based on the above equation.

The high-frequency envelope gain information Ĉ_{high}(0, l) calculated by the high-frequency envelope gain estimating unit 124 based on (Equation 9) is supplied to the high-frequency envelope correcting unit 127.

### (2.8 Concerning Mid-Frequency Envelope Correcting Unit)

Next, description will be given of the processing by the mid-frequency envelope correcting unit 126 provided in the analysis processing unit 120 shown in FIG. 1.

The mid-frequency envelope correcting unit 126 in the analysis processing unit 120 inputs the time frequency spectrum Xana(k, l) generated by the frequency analysis unit 121 in the analysis processing unit 120 based on the input sound signal 81.

Moreover, the mid-frequency envelope correcting unit 126 in the analysis processing unit 120 inputs the low-frequency cepstrum C_{low}(i, l) generated by the low-frequency envelope calculating unit 122 in the analysis processing unit 120 based on the input sound signal 81.

The mid-frequency envelope correcting unit 126 uses mid-frequency band part of the time frequency spectrum Xana(k, l) generated by the frequency analysis unit 121 based on the input sound signal 81, for example, a part corresponding to a spectrum of equal to or greater than fs1/4 and equal to or less than fs1/2, and the low-frequency cepstrum C_{low}(i, l) supplied from the low-frequency envelope calculating unit 122 to generate a spectrum signal which has been flattened on a frequency axis.

First, coefficients of the cepstrum other than lower degree coefficients are set to 0 in the low-frequency cepstrum C_{low}(i, l) and then returned into a power spectrum domain to obtain a lifter low-frequency spectrum X_{lift}_{_{—}}₁(k, l) based on the following (Equation 10).

$${X}_{lift\_l} ( k , l ) = exp ( {\sum }_{i = 0}^{M - 1} {C}_{low} ( i , l ) * exp ( - j 2 π \frac{i * k}{M} ) ) \qquad EQUATION 10$$

Next, the mid-frequency envelope correcting unit 126 uses a part (k=M/4, . . . , M/2 in this case) corresponding to a spectrum of the mid-frequency part (equal to or more than fs1/4 and equal to or less than fs1/2) of the lifter low-frequency spectrum X_{lift}_{_{—}}₁(k) obtained based on (Equation 10) to divide the same frequency part of the time frequency spectrum Xana(k, l), performs flattening, and then performs mirroring on the lower-frequency side than the frequency of fs1/4 to obtain a mid-frequency spectrum Xwhite(k, l).

The mid-frequency spectrum Xwhite(k, l) is calculated based on the following (Equation 11).

$${X}_{mid} ( k , l ) = \frac{{X}_{ana} ( k , l )}{{X}_{lif t\_l} ( k , l )} \\ k = \frac{M}{4} , … , \frac{M}{2} \\ {X}_{white} ( k , l ) = \{ \begin{matrix}conj ( {X}_{mid} ( \frac{M}{2} - k , l ) ) & k = 0 , … , \frac{M}{4} - 1 \\ {X}_{mid} ( k , l ) & k = \frac{M}{4} , … , \frac{M}{2}\end{matrix} \qquad EQUATION 11$$

The mid-frequency spectrum Xwhite(k, l) calculated by the mid-frequency envelope correcting unit 126 based on (Equation 10) and (Equation 11) is supplied to the high-frequency envelope correcting unit 127.

### (2.9 Concerning High-Frequency Envelope Correcting Unit)

Next, description will be given of the processing by the high-frequency envelope correcting unit 127 provided in the analysis processing unit 120 shown in FIG. 1.

The high-frequency envelope correcting unit 127 in the analysis processing unit 120 inputs the mid-frequency spectrum Xwhite(k, l) generated by the mid-frequency envelope correcting unit 126 in the analysis processing unit 120 based on the input sound signal 81.

Moreover, the high-frequency envelope correcting unit 127 in the analysis processing unit 120 inputs the high-frequency envelope gain information C_{high}(0, l) of the input sound signal 81 estimated by the high-frequency envelope gain estimating unit 124 in the analysis processing unit 120 with the use of the envelope gain information as the learned data.

Furthermore, the high-frequency envelope correcting unit 127 in the analysis processing unit 120 inputs the high-frequency envelope shape information C_{high}(i, h) of the input sound signal 81 estimated by the high-frequency envelope shape estimating unit 125 in the analysis processing unit 120 with the use of the envelope shape information as the learned data.

The high-frequency envelope correcting unit 127 corrects the high-frequency envelope information of the input sound signal 81 based on such input information. The specific processing is as follows.

The high-frequency envelope correcting unit 127 inputs the mid-frequency spectrum Xwhite(k, l) generated by the mid-frequency envelope correcting unit 126 based on the input sound signal 81 and uses the high-frequency envelope gain information C_{high}(0, l) generated by the high-frequency envelope gain estimating unit 124 and the high-frequency envelope gain information C_{high}(i, l) (here, i=1, . . . , R) generated by the high-frequency envelope shape estimating unit 125 for the mid-frequency spectrum Xwhite(k, l) to correct the envelope.

First, the high-frequency envelope gain information C_{high}(0, l) generated by the high-frequency envelope gain estimating unit 124 and the high-frequency envelope gain information C_{high}(i, l) generated by the high-frequency envelope shape estimating unit 125 are returned into the envelope information by the power spectrum to obtain the lifer high-frequency spectrum X_{lift}_{_{—}}ₕ(k, l) based on the following (Equation 12).

$${X}_{lift\_h} ( k , l ) = exp ( {\sum }_{i = 0}^{M - 1} {{C}^{{\hat{}}^{⋒}}}_{high} ( i , l ) * exp ( - j2π \frac{i * k}{M} ) ) \qquad EQUATION 12$$

The high-frequency envelope correcting unit 127 applies the lifter high-frequency spectrum X_{lift}_{_{—}}ₕ(k, l) obtained based on (Equation 12), corrects the mid-frequency spectrum Xwhite(k, l) based on the following (Equation 13), and obtains the corrected mid-frequency spectrum X′white(k, l).

X′_{white}(k,l)=X_{white}(k,l)*X_{lift}_{_{—}}ₕ(k,l) EQUATION 13

Moreover, the high-frequency envelope correcting unit 127 inverts the spectrum X′white(k, l) corrected based on (Equation 12) about the frequency of fs1/2 (k=M/2 in this case), inserts 0 into the lower-frequency spectrum at which a spectrum is originally present, and obtains the high-frequency spectrum Xhigh(k, l) shown in the following (Equation 14).

$${X}_{high} ( k , l ) = \{ \begin{matrix}0 & k = 0 , … , \frac{M}{2} - 1 \\ conj ( {X}_{white}^{′} ( M - k , l ) ) & k = \frac{M}{2} , … , M - 1 \\ {X}_{white}^{′} ( k , l ) & k = M , … , \frac{3 M}{2} \\ 0 & k = \frac{3 M}{2} + 1 , … , 2 M - 1\end{matrix} \qquad EQUATION 14$$

As a result, a high-frequency spectrum Xhigh(k, l) signal of a frequency fs2 (the FFT point number is 2M in this case) is generated.

The high-frequency spectrum Xhigh(k, l) generated by the high-frequency envelope correcting unit 127 is supplied to the frequency synthesizing unit 128.

### (2.10 Concerning Frequency Synthesizing Unit)

Next, description will be given of the processing by the frequency synthesizing unit 128 provided in the analysis processing unit 120 shown in FIG. 1.

The frequency synthesizing unit 128 inputs the high-frequency spectrum Xhigh(k, l) from the high-frequency envelope correcting unit 127 in the analysis processing unit 120.

Moreover, the frequency synthesizing unit 128 inputs the frequency spectrum Xana(k, l) generated by the frequency analysis unit 121 based on the input sound signal 81.

The frequency synthesizing unit 128 uses the high-frequency spectrum Xhigh(k, l) from the high-frequency envelope correcting unit 127 in the analysis processing unit 120 and a part corresponding to the frequency spectrum Xana(k, l) (k=0, . . . , M/2 in this case), which has been supplied from the frequency analysis unit 121, corresponding to the frequency of equal to or more than 0 and equal to or less than fs1/2 to obtain the synthesized spectrum Xsyn(k, l) based on the following (Equation 15).

$${X}_{syn} ( k , l ) = \{ \begin{matrix}{X}_{ana} ( k , l ) & k = 0 , … , \frac{M}{2} - 1 \\ \frac{{X}_{ana} ( k , l ) + {X}_{high} ( k , l )}{2} & k = \frac{M}{2} \\ {X}_{high} ( k , l ) & k = \frac{M}{2} + 1 , … , \frac{3 M}{2} - 1 \\ \frac{{X}_{ana} ( 2 M - k , l ) + {X}_{high} ( k , l )}{2} & k = \frac{3 M}{2} \\ conj ( {X}_{ana} ( 2 M - k , l ) ) & k = \frac{3 M}{2} + 1 , … , 2 M - 1\end{matrix} \qquad EQUATION 15$$

The frequency synthesizing unit 128 performs reverse frequency conversion on the synthesized spectrum Xsyn(k, l) calculated based on (Equation 15) to obtain a synthesized signal xsyn(n, l) of the time domain.

The synthesized signal xsyn(n, l) of the time domain is obtained based on the following (Equation 16).

$${x}_{syn} ( n , l ) = \frac{1}{m} {\sum }_{k = 0}^{M - 1} {X}_{syn} ( k , l ) * exp ( j 2 π n \frac{k}{M} ) \qquad EQUATION 16$$

Although IDFT (inverse discrete Fourier transform) is used as the reverse frequency conversion in this embodiment, transform corresponding to the reverse transform with respect to the transform used by the frequency analysis unit may be used. However, since the frame size N corresponds to the sample number (N=sampling frequency of fs2*0.02) corresponding to 0.02 sec in the expanded frequency fs2, and the DFT point number M is a value which is equal to or greater than N and a power of two, it is necessary to pay attention to the fact that the sizes are different from those of N and M used in the above description.

The frequency synthesizing unit 128 performs frame synthesis and generates an output signal y(n) by multiplying the synthesized signal xsyn(n, l) calculated based on (Equation 16) by a window function w_syn(n) and performing overlapped addition.

A specific equation for calculating the output signal y(n) and the window function w_syn(n) will be shown in the following (Equation 17).

$$y ( n + ; * N ) = {x}_{syn} ( n , l ) * {w}_{syn} ( n ) + y ( n + l * N ) \\ {w}_{syn} ( n ) = \{ \begin{matrix}{( 0.5 - 0.5 * cos ( 2 π \frac{n}{N} ) )}^{0.5} & n = 0 , … , N - 1 \\ 0 & n = N , … , M - 1\end{matrix} \qquad EQUATION 17$$

Although the 50% overlapped addition is performed using the square root of a Hanning window as the window function in the above processing, another window such as a sine window or the like or an overlapping ratio other than 50% may be used.

The signal y(n) calculated by the frequency synthesizing unit 128 based on (Equation 17) is output as an output sound signal 82 of the sound signal processing apparatus 100 shown in FIG. 1.

The output sound signal 82 has a sampling frequency (fs2) and becomes a sound signal, which has a double sampling frequency of the sampling frequency (fs1) of the input sound signal, in which a frequency band has been expanded.

Although the above embodiment was described as a configuration example in which the sound signal processing apparatus 100 shown in FIG. 1 was provided with the two processing units including the learning processing unit 110 and the analysis processing unit 120, another configuration is also applicable in which the learned data obtained as a result of the learning by the learning processing unit 110 is stored in advance in a storage unit. That is, a configuration is also applicable in which the analysis processing unit 120 obtains, if necessary, the learned data stored in the storage unit to perform processing on the input signal. In the case of such a configuration, it is possible to configure the sound signal processing apparatus by the analysis processing unit, from which the learning processing unit is omitted, and the storage unit which stores the learned data as a result of learning.

The present disclosure was described in detail with reference to specific embodiments. However, it is obvious that those who skilled in the art can make modifications or alterations of the embodiments within the scope of the present disclosure. That is, the present disclosure was described as exemplification and should not be understood as limitations. In order to determine the scope of the present disclosure, the appended claims should be referred to.

In addition, a series of processing described in this specification can be executed by hardware, software, or a composite configuration of both. When the processing is executed by software, a program recording a processing sequence may be installed on a memory within a computer embedded in dedicated hardware, or the program may be installed on a general computer capable of executing various kinds of processing. For example, the program may be recorded in advance in a recording medium. In addition to a configuration in which the program is installed on a computer from a recording medium, it is also possible to receive the program via a network such as LAN (Local Area Network), the Internet, or the like and install the program on a recording medium such as a built-in hard disk or the like.

Moreover, the various kinds of processing described in this specification may be executed in a time-series manner in order of the description or may be executed in parallel or in an independent manner in accordance with the processing abilities of the apparatuses which execute the processing or in accordance with the necessity. In addition, a system in this specification means a logical composite configuration including a plurality of apparatuses and is not limited to a configuration in which each apparatus with a configuration is provided in the same case body.

The present disclosure contains subject matter related to that disclosed in Japanese Priority Patent Application JP 2011-026241 filed in the Japan Patent Office on Feb. 9, 2011, the entire contents of which are hereby incorporated by reference.

What is claimed is:

1. A sound signal processing apparatus comprising:
a frequency analysis unit which executes frequency analysis of an input sound signal;
a low-frequency envelope calculating unit which calculates low-frequency envelope information as envelope information of a low-frequency band based on a result of the frequency analysis by the frequency analysis unit;
a high-frequency envelope information estimating unit which applies learned data generated in advance based on a sound signal for learning, which is learned data for calculating high-frequency envelope information as envelope information of a high-frequency band from the low-frequency envelope information, and generates estimated high-frequency envelope information corresponding to an input signal from the low-frequency envelope information corresponding to the input sound signal; and
a frequency synthesizing unit which synthesizes a high-frequency band signal corresponding to the estimated high-frequency envelope information generated by the high-frequency envelope information estimating unit with the input sound signal and generates an output sound signal in which a frequency band is expanded.

2. The sound signal processing apparatus according to claim 1,
wherein the learned data includes
envelope gain information with which high-frequency envelope gain information is estimated from low-frequency envelope gain information, and
envelope shape information with which high-frequency envelope shape information is estimated from low-frequency envelope shape information, and
wherein the high-frequency envelope information estimating unit includes
a high-frequency envelope gain estimating unit which applies the envelope gain information included in the learned data and estimates the estimated high-frequency envelope gain information corresponding to the input signal from the low-frequency envelope gain information corresponding to the input sound signal, and
a high-frequency envelope shape estimating unit which applies the envelope shape information included in the learned data and estimates the estimated high-frequency envelope shape information corresponding to the input signal from the low-frequency envelope shape information corresponding to the input sound signal.

3. The sound signal processing apparatus according to claim 2,
wherein the high-frequency envelope shape estimating unit inputs shaped low-frequency envelope information generated by filtering processing on the low-frequency envelope information of the input sound signal, which has been calculated by the low-frequency envelope calculating unit, and estimates the estimated high-frequency envelope shape information corresponding to the input signal.

4. The sound signal processing apparatus according to claim 1,
wherein the frequency analysis unit performs time frequency analysis on the input sound signal and generates a time frequency spectrum.

5. The sound signal processing apparatus according to claim 1,
wherein the low-frequency envelope calculating unit inputs a time frequency spectrum of the input sound signal, which has been generated by the frequency analysis unit, and generates a low-frequency cepstrum.

6. The sound signal processing apparatus according to claim 1,
wherein the high-frequency envelope information estimating unit includes
a high-frequency envelope gain estimating unit which applies the envelope gain information included in the learned data and estimates the estimated high-frequency envelope gain information corresponding to the input signal from the low-frequency envelope gain information corresponding to the input sound signal, and
wherein the high-frequency envelope gain estimating unit applies the envelope gain information included in the learned data to low-frequency cepstrum information generated based on the input sound signal and estimates the estimated high-frequency envelope gain information corresponding to the input signal from the low-frequency envelope gain information corresponding to the input sound signal.

7. The sound signal processing apparatus according to claim 1,
wherein the high-frequency envelope information estimating unit includes
a high-frequency envelope shape estimating unit which applies the envelope shape information included in the learned data and estimates the estimated high-frequency envelope shape information corresponding to the input signal from the low-frequency envelope shape information corresponding to the input sound signal, and
wherein the high-frequency envelope shape estimating unit estimates the high-frequency envelope shape information corresponding to the input sound signal by processing with the use of the envelope shape information included in the learned data, based on shaped low-frequency cepstrum information generated based on the input sound signal.

8. The sound signal processing apparatus according to claim 7,
wherein the high-frequency envelope shape estimating unit estimates the high-frequency envelope shape information corresponding to the input sound signal by estimation processing with the use of GMM (Gaussian mixture model).

9. The sound signal processing apparatus according to claim 1, further comprising:
a learning processing unit which generates the learned data based on the sound signal for learning including a frequency in a high-frequency band, which is not included in the input sound signal,
wherein the high-frequency envelope information estimating unit applies the learned data generated by the learning processing unit and generates the estimated high-frequency envelope information corresponding to the input signal from the low-frequency envelope information corresponding to the input sound signal.

10. A sound signal processing apparatus comprising:
a function of calculating first envelope information from a first signal;
a function of removing a DC component of the first envelope information in a time direction by filtering for the purpose of removing an environmental factor which includes at least one of a function of collecting sound and a delivering function; and
a function of regarding second envelope information, which has obtained by linearly converting the first envelope information after the filtering, as envelope information of a second signal and synthesizing the second signal with the first signal.

11. A sound signal processing apparatus comprising:
a function of calculating low-frequency envelope information from a low-frequency signal;
a function of calculating a ratio at which the low-frequency envelope information belongs to a plurality of groups classified in advance by learning a large amount of data;
a function of performing linear conversion on the low-frequency envelope information had on linear conversion equations respectively allotted to the plurality of groups and generating a plurality of high-frequency envelope information items; and
a function of regarding high-frequency envelope information, which has been obtained by mixing the plurality of high-frequency envelope information items at a ratio at which the high-frequency envelope information items belong to the plurality of groups for the further purpose of generating smooth high-frequency envelope information in a time axis, as envelope information of a high-frequency signal and synthesizing the high-frequency signal with the low-frequency signal.

12. A sound signal processing method according to which frequency band expansion processing is performed on an input sound signal in a sound signal processing apparatus, the method comprising:
executing frequency analysis of an input sound signal by a frequency analysis unit;
calculating low-frequency envelope information as envelope information of low-frequency band based on a result of executing the frequency analysis by a low-frequency envelope calculating unit;
applying learned data generated in advance based on a sound signal for learning by a high-frequency envelope information estimating unit, which is learned data for calculating high-frequency envelope information as envelope information of a high-frequency band from the low-frequency envelope information, and generating estimated high-frequency envelope information corresponding to an input signal from the low-frequency envelope information corresponding to the input sound signal; and
synthesizing by a frequency synthesizing unit a high-frequency band signal corresponding to the estimated high-frequency envelope information generated by the high-frequency envelope information estimating unit with the input sound signal and generating an output sound signal in which a frequency band is expanded.

13. A sound signal processing method according to which frequency band expansion processing is performed on an input sound signal in a sound signal processing apparatus, the method comprising:
calculating first envelope information from a first signal;
removing a DC component of the first envelope information in a time direction by filtering for the purpose of removing an environmental factor which includes at least one of a function of collecting sound and a delivering function; and
regarding second envelope information, which has obtained by linearly converting the first envelope information after the filtering, as envelope information of a second signal and synthesizing the second signal with the first signal.

14. A sound signal processing method according to which frequency band expansion processing is performed on an input sound signal in a sound signal processing apparatus, the method comprising:
calculating low-frequency envelope information from a low-frequency signal;
calculating a ratio at which the low-frequency envelope information belongs to a plurality of groups classified in advance by learning a large amount of data;
performing linear conversion on the low-frequency envelope information based on linear conversion equations respectively allotted to the plurality of groups and generating a plurality of high-frequency envelope information items; and
regarding high-frequency envelope information, which has been obtained by mixing the plurality of high-frequency envelope information items at a ratio at which the high-frequency envelope information items belong to the plurality of groups for the purpose of generating smooth high-frequency envelope information in a time axis, as envelope information of a high-frequency signal and synthesizing the high-frequency signal with the low-frequency signal.

15. A program which causes a sound signal processing apparatus to perform frequency band expansion processing on an input sound signal, the program comprising:
causing a frequency analysis unit to execute frequency analysis of an input sound signal;
causing a low-frequency envelope calculating unit to calculate low-frequency envelope information as envelope information of low-frequency band based on a result of executing the frequency analysis;
causing a high-frequency envelope information estimating unit to apply learned data generated in advance based on a sound signal for learning by, which is learned data for calculating high-frequency envelope information as envelope information of a high-frequency band from the low-frequency envelope information, and generate estimated high-frequency envelope information corresponding to an input signal from the low-frequency envelope information corresponding to the input sound signal; and
causing a frequency synthesizing unit to synthesize a high-frequency band signal corresponding to the estimated high-frequency envelope information generated by the high-frequency envelope information estimating unit with the input sound signal and generate an output sound signal in which a frequency band is expanded.
